(19) United States
(12) Patent Application Publication
(10) Pub. No.: US 2024/0339811 A1
(43) Pub. Date: Oct. 10, 2024

(54) SEMICONDUCTOR OPTICAL DEVICE

(71) Applicant: Mitsubishi Electric Corporation, Tokyo (JP)

(72) Inventor: Yusuke AZUMA, Tokyo (JP)

(73) Assignee: Mitsubishi Electric Corporation, Tokyo (JP)

(21) Appl. No.: 18/579,335

(22) PCT Filed: Dec. 27, 2021
(86) PCT No.: PCT/JP2021/048613

§ 371 Date: Jan. 13, 2024

(51) Int. Cl. H01S 5/042; H01S 5/026

(52) U.S. Cl. CPC H01S 5/04256; H01S 5/0265; H01S 5/04254

(57) ABSTRACT

A laser diode (2) and a modulator (3) are provided on a semiconductor substrate (1). A modulator (3) has a modulator electrode (8) and modulates laser light emitted from the laser diode (2). A plurality of lead-out electrodes (9) are led out from the modulator electrode (8). A plurality of electrode pads (10) respectively faces the plurality of lead-out electrodes (9). A gap (11) is provided between the lead-out electrode (9) and the electrode pad (10) facing each other.

### FIELD

The present disclosure relates to a semiconductor optical device.

### BACKGROUND

In an access system that is an optical communication system between a relay station and a user, a direct modulation semiconductor laser transmitter (DML: Directly Modulated Laser) suitable for low speed modulation has often been used. However, when high speed communication at 10 Gb/s or higher is performed, a semiconductor optical device (EML: Electro-absorption Modulator integrated Laser) in which a laser diode, which is a light source, and an electro-absorption semiconductor optical modulator (EAM: Electro-absorption Modulator, hereinafter refereed to as EA modulator) suitable for high speed modulation are integrated on the same substrate is used.

In a semiconductor optical device of the related art, only one electrode pad for bonding of a wire for application of a modulation signal is provided on the left or right side of the chip and is connected to an electrode of the modulator in advance. When the wire is attached from the opposite side of the location of the electrode pad in the left and right direction because of the configuration of the transceiver, the wire is increased in length and high frequency characteristics may be deteriorated.

Furthermore, semiconductor optical devices are used in transceivers for various uses. The transceivers are variously designed. In some case, a signal line on a signal input side is on the left side of a chip in one transceiver and is on the right side in another transceiver. If an electrode pad of the semiconductor optical device is present only on one of the left side and the right side of the chip, the wire can be reduced in length for the one transceiver, but the wire is increased in length for the other transceiver and high frequency characteristics are deteriorated.

In order to avoid this problem and enable one semiconductor optical device to support a plurality of transceiver designs, it has been proposed to locate an electrode pad on each of the left and right sides and attach a wire to appropriate one electrode pad according to a transceiver design (see, for example. PTL1).

### CITATION LIST

### Patent Literature

[PTL1] JP 2011-232567 A

### SUMMARY OF THE INVENTION

### Problem to be Solved by the Invention

However, since both of the electrode pads on the left and right sides are connected to a modulator electrode, there has been a problem in that high frequency characteristics are deteriorated by being affected by parasitic capacitance of both of the electrode pads.

The present disclosure has been devised in order to solve the problem described above. An object of the present disclosure is to obtain a semiconductor optical device that can reduce deterioration in high frequency characteristics.

### Solution to Problem

A semiconductor optical device according to the present disclosure includes: a semiconductor substrate; a laser diode provided on the semiconductor substrate; a modulator provided on the semiconductor substrate, having a modulator electrode, and modulating laser light emitted from the laser diode: a plurality of lead-out electrodes led out from the modulator electrode; and a plurality of electrode pads respectively facing the plurality of lead-out electrodes, wherein a gap is provided between the lead-out electrode and the electrode pad facing each other.

### Advantageous Effects of Invention

In the present disclosure, since the electrode pad not wire-bonded is not connected to the modulator electrode, the parasitic capacitance component of this electrode pad has no effect. Therefore, it is possible to reduce deterioration in high frequency characteristics.

### BRIEF DESCRIPTION OF THE DRAWINGS

FIG. 1 is a top view illustrating a semiconductor optical device according to a first embodiment.

FIG. 2 is a sectional view taken along I-II in FIG. 1.

FIG. 3 is a top view illustrating the modulator electrode, the lead-out electrodes, and the electrode pads according to the first embodiment.

FIG. 4 is an enlarged top view of the lead-out electrode and the electrode pad according to the first embodiment.

FIG. 5 is a top view illustrating a semiconductor optical device according to a second embodiment.

FIG. 6 is a top view illustrating a modulator electrode, lead-out electrodes, and electrode pads according to a third embodiment.

FIG. 7 is a top view illustrating a modulator electrode, lead-out electrodes, and electrode pads according to a fourth embodiment.

FIG. 8 is a top view illustrating a modulator electrode, lead-out electrodes, and electrode pads according to a fifth embodiment.

FIG. 9 is a top view illustrating a modulator electrode, lead-out electrodes, and electrode pads according to a sixth embodiment.

### DESCRIPTION OF EMBODIMENTS

A semiconductor optical device according to the embodiments of the present disclosure will be described with reference to the drawings. The same components will be denoted by the same symbols, and the repeated description thereof may be omitted.

### First Embodiment

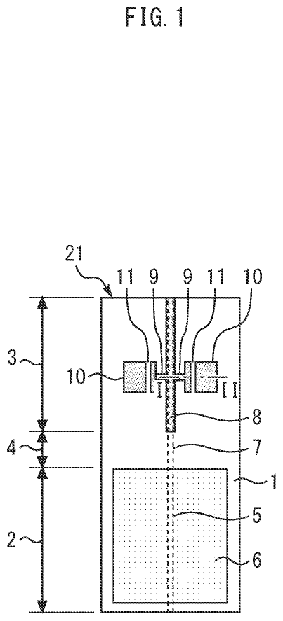

FIG. 1 is a top view illustrating a semiconductor optical device according to a first embodiment. A laser diode 2 and an EA modulator 3 are integrated on an n-type InP substrate 1. A separation region 4 is provided between the laser diode 2 and the EA modulator 3 to electrically separate the laser diode 2 and the EA modulator 3.

The laser diode 2 is typically configured by a distributed feedback laser structure. The laser diode 2 includes a first core layer 5 that guides laser light. The first core layer 5 functions as an active layer of the laser diode 2. In the laser diode 2, a p electrode 6 is provided on the front surface side of the n-type InP substrate 1. An n electrode, which is a cathode electrode, is provided on the rear surface side and electrically connected to the n-type InP substrate 1.

The EA modulator 3 includes a second core layer 7 that guides and modulates the laser light generated by the laser diode 2. In the separation region 4, unlike in the EA modulator 3, optical modulation of the laser light generated by the laser diode 2 is not performed. However, since the structure of the core layer of the separation region 4 as an optical waveguide has the same configuration as the core layer of the EA modulator 3, the core layer of the separation region 4 is also referred to as second core layer 7 for convenience.

In the EA modulator 3, a modulator electrode 8 is provided on the front surface side of the n-type InP substrate 1 in order to apply a voltage to the second core layer 7. A plurality of lead-out electrodes 9 are led out from the modulator electrode 8 to the left and right sides. A plurality of electrode pads 10 are provided on the front surface side of the n-type InP substrate 1 and respectively face T-shaped tips of the plurality of lead-out electrodes 9. Here, one electrode pad 10 is provided on each of the left and right sides of the modulator electrode 8. A gap 11 is provided between the lead-out electrode 9 and the electrode pad 10 facing each other. Therefore, the modulator electrode 8 and the electrode pads 10 are not conducted. For example, the length of the modulator electrode 8 in the optical waveguide direction is 200 μm.

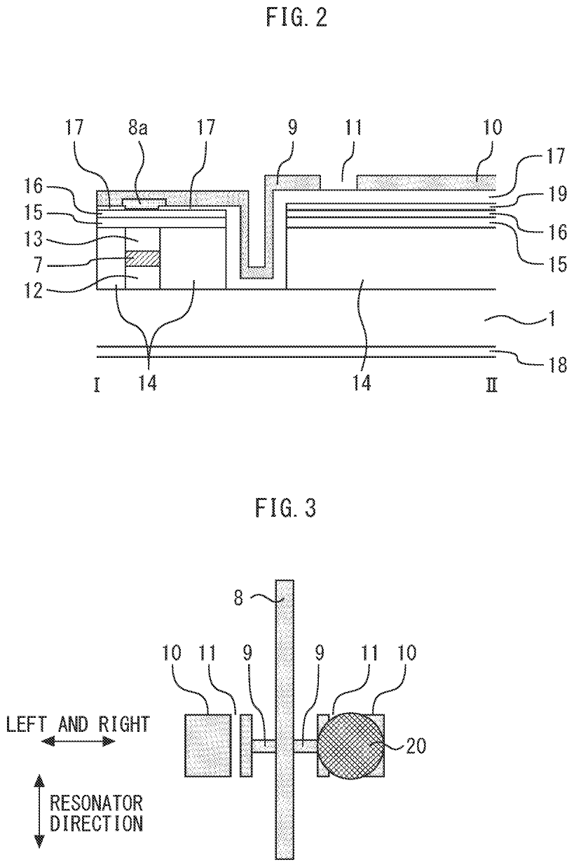

FIG. 2 is a sectional view taken along I-II in FIG. 1. An n-type InP clad layer 12, the second core layer 7, and a p-type InP clad layer 13 are provided on the n-type InP substrate 1 in this order. Current block layers 14 are provided on both sides of the second core layer 7. The current block layer 14 is, for example, a stacked structure of a p-type InP layer, an n-type InP layer, and a p-type InP layer. A p-type InP layer 15 and a p-type contact layer 16 are provided in this order on the p-type InP clad layer 13 and the current block layer 14. A first layer 8a of the modulator electrode 8 is connected to the p-type contact layer 16 via an opening of an insulating film 17. The lead-out electrodes 9 are electrically connected to the first layer 8a of the modulator electrode 8. A cathode electrode 18 is provided on the lower surface of the n-type InP substrate 1.

The lead-out electrode 9 and the electrode pad 10 are not electrically connected and the gap 11 is provided between the lead-out electrode 9 and the electrode pad 10. A p-type InP layer 19 is provided between the insulating film 17 and the p-type contact layer 16 below the electrode pads 10 in order to improve adhesion to the insulating film 17.

The materials of the first layer Sa of the modulator electrode 8 are, for example, Ti, Pt, and Au. For example, the thickness of Ti is 500 A, the thickness of Pt is 500 A, and the thickness of Au is 2000 A. The materials of the electrode pads 10 and the lead-out electrodes 9 are, for example, Ti and Au. For example, 3 μm thick Au plating is provided on a layer of Ti having the thickness of 500 A and a layer of Au having the thickness of 2000 A.

The first core layer 5 of the laser diode 2 is configured by, for example, an AlGalnAs-based or InGaAsP-based multiple quantum well layer having a bandgap wavelength of 1.2 to 1.62 μm. On the other hand, the second core layer 7 of the EA modulator 3 is configured by, for example, an AlGalnAs-based or InGaAsP-based multiple quantum well layer having a bandgap wavelength of 0.9 to 1.55 μm. That is, the bandgap wavelength of the second core layer 7 is set to be shorter than the oscillation wavelength of the laser diode 2.

The first core layer 5 and the EA modulator 3 may be formed using a selective growth technique or may be separately grown by Butt-joint growth and connected. It is preferable not to provide the p-type contact layer 16 in the separation region 4. Consequently, a loss of laser light decreases and isolation resistance between the laser diode 2 and the EA modulator 3 increases.

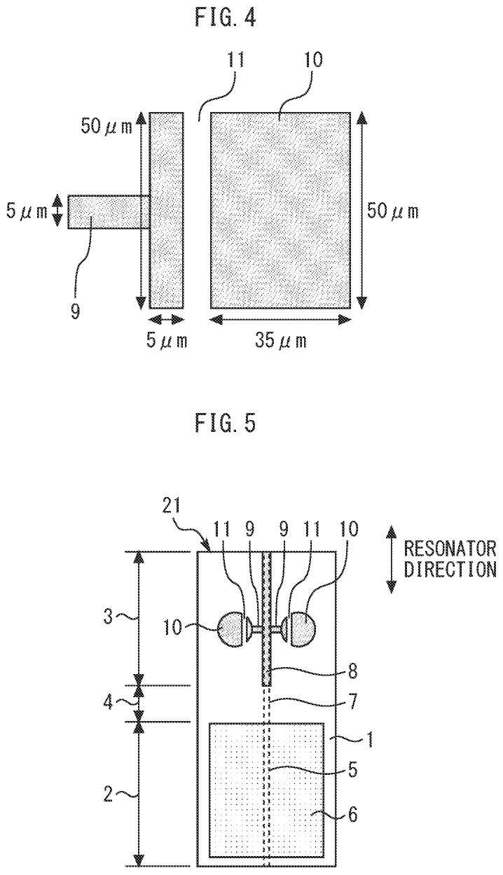

FIG. 3 is a top view illustrating the modulator electrode, the lead-out electrodes, and the electrode pads according to the first embodiment. FIG. 4 is an enlarged top view of the lead-out electrode and the electrode pad according to the first embodiment. The electrode pad 10 is a rectangle having the length of 50 μm in the optical waveguide direction and the length of 35 μm in the left and right direction. The tip of the lead-out electrode 9 has a T shape having the width of 5 μm. The length of the wide portion of the T shape in the left and right direction is 25 μm on one side and the length of the T shape in the resonator direction is 50 μm. The wide portion of the T shape of the lead-out electrode 9 faces one side of the electrode pad 10. The gap 11 between the wide portion of the T shape of the lead-out electrode 9 and the electrode pad 10 has the width of 5 μm.

A wire 20 for modulation signal input is bonded to one of the plurality of electrode pads 10. For example, the diameter of the wire 20 is 60 μm. The wire 20 is bonded to the lead-out electrode 9 and the electrode pad 10 facing each other across the gap 11. Consequently, the electrode pad 10 to which the wire 20 is bonded is electrically connected to the modulator electrode 8. On the other hand, the electrode pad 10 to which the wire 20 is not bonded is not electrically connected to the modulator electrode 8.

Subsequently, the operation of the semiconductor optical device explained above is explained. When a forward current is fed to the laser diode 2, laser oscillation occurs and laser light is emitted from the laser diode 2. This light is propagated to the EA modulator 3 and emitted from an emission end face 21. The EA modulator 3 has an electro-absorption effect of a light absorption amount increasing when a reverse bias voltage is applied to the EA modulator 3. Using this effect, the laser light is modulated according to the magnitude of the voltage applied to the EA modulator. This reverse bias voltage is, for example, a 25 Gbps modulation signal and is applied through the wire 20.

At this time, the electrode pad 10 on the right side wire-bonded and connected to the modulator electrode 8 becomes a parasitic capacitance component. On the other hand, the parasitic capacitance component of the electrode pad 10 on the left side not wire-bonded and not connected to the modulator electrode 8 has no effect.

As explained above, in this embodiment, the plurality of electrode pads 10 are provided for one modulator electrode 8. It is possible to select an electrode pad 10 to which the wire 20 for modulation signal input is short and attach the wire 20 to it according to the design of a transceiver. Consequently, band deterioration is suppressed. Since one semiconductor optical device can support a plurality of transceiver designs, element production efficiency is high. Furthermore, since the electrode pad 10 not wire-bonded is not connected to the modulator electrode 8, the parasitic capacitance component of this electrode pad 10 has no effect. Therefore, it is possible to reduce deterioration in high frequency characteristics.

The width of the gap 11 needs to be set to 3 μm or more in order to secure insulation between the lead-out electrode 9 and the electrode pad 10. In addition, the width of the gap 11 between the lead-out electrode 9 and the electrode pad 10 facing each other needs to be set to 10 μm or less in order to secure adhesion of the wire bonding between the lead-out electrode 9 and the electrode pad 10 and the wire 20.

The widths of portions facing each other of the lead-out electrode 9 and the electrode pad 10 are the same. Therefore, since low position accuracy of the wire bonding for connecting them may be accepted, it is possible to improve the yield. Although the widths of the portions facing each other of the lead-out electrode 9 and the electrode pad 10 may be different, higher position accuracy of the wire bonding is required.

### Second Embodiment

FIG. 5 is a top view illustrating a semiconductor optical device according to a second embodiment. An electrode pad 10 is a partially cut circle. For example, the diameter of the circle is 50 μm. Consequently, the area of the electrode pad 10 can be set smaller than when the electrode pad 10 is a square and its parasitic capacitance can be reduced. Since wire bonding of a wire 20 is circular, it is possible to secure a necessary adhesion area of the wire bonding and the electrode pad 10.

### Third Embodiment

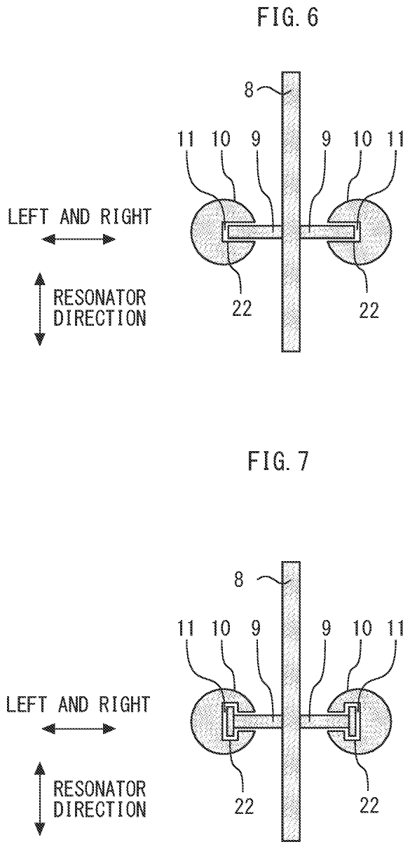

FIG. 6 is a top view illustrating a modulator electrode, lead-out electrodes, and electrode pads according to a third embodiment. Lead-out electrodes 9 are led out from a modulator electrode 8 to the left and right sides. The linear tip of the lead-out electrode 9 enters a cutout 22 of the electrode pad 10. For example, the lead-out electrode 9 has the width of 5 μm and the entire length of 60 μm. The width of a gap 11 is 5 μm. Since lower position accuracy, in the left and right direction, of wire bonding of a wire 20 than the position accuracy in the first embodiment may be accepted, it is possible to improve the yield.

### Fourth Embodiment

FIG. 7 is a top view illustrating a modulator electrode, lead-out electrodes, and electrode pads according to a fourth embodiment. Lead-out electrodes 9 are led out from a modulator electrode 8 to the left and right sides. The T-shaped tip of the lead-out electrode 9 enters a cutout 22 of an electrode pad 10. For example, the lead-out electrode 9 has the width of 5 μm and the length of 70 μm in the left and right direction. The length of the wide portion of the T shape of the lead-out electrode 9 in the resonator direction is 20 μm. The width of a gap 11 is 5 μm. Since lower position accuracy, in the up-down direction, of wire bonding of a wire 20 than the position accuracy in the third embodiment may be accepted, it is possible to improve the yield.

### Fifth Embodiment

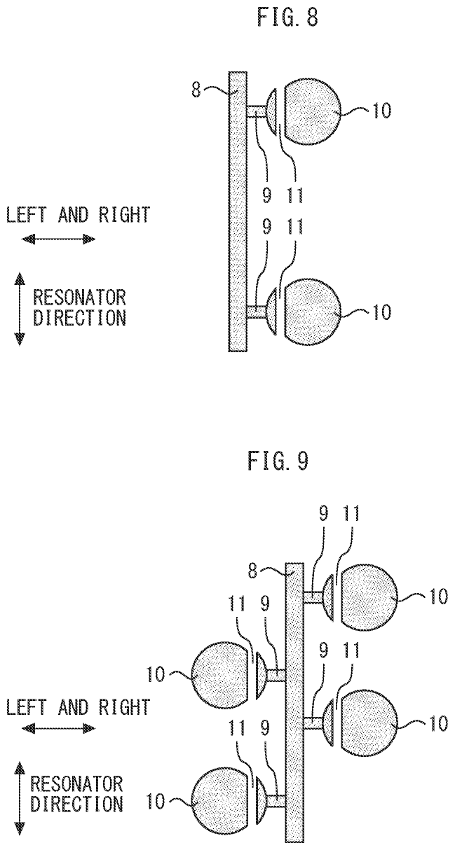

FIG. 8 is a top view illustrating a modulator electrode, lead-out electrodes, and electrode pads according to a fifth embodiment. A plurality of electrode pads 10 are located only on one side of a modulator electrode 8. A plurality of lead-out electrodes 9 are provided to respectively face the plurality of electrode pads 10. For example, the entire length of the modulator electrode 8 is 200 μm and two lead-out electrodes 9 are led out from positions at 40 μm from both ends of the modulator electrode 8. The shapes of the lead-out electrodes 9 and the electrode pads 10 are the same as the shapes in the second embodiment.

A semiconductor optical device according to this embodiment can be used in transceivers in designs in which the positions of a wire 20 for modulation signal input are different. That is, for each transceiver design, one of the plurality of electrode pads 10 is selected and the wire 20 is bonded to it such that the wire 20 is reduced in length. Consequently, it is possible to reduce deterioration in high frequency characteristics.

### Sixth Embodiment

FIG. 9 is a top view illustrating a modulator electrode, lead-out electrodes, and electrode pads according to a sixth embodiment. Pluralities of electrode pads 10 are located on both the left and right sides of a modulator electrode 8. For example, the entire length of the modulator electrode 8 is 200 μm and four electrode pads 10 are alternately provided on the left and right sides at intervals of 40 μm. Four lead-out electrodes 9 are provided to respectively face the four electrode pads 10.

A semiconductor optical device according to this embodiment can be used in transceivers in designs in which the positions of a wire 20 are different. That is, for each transceiver design, one of the plurality of electrode pads 10 is selected and the wire 20 is bonded to it such that the wire 20 is reduced in length. Consequently, it is possible to reduce deterioration in high frequency characteristics. Since it supports the positions of the wire 20 of the transceivers on the left and right sides, flexibility of design is higher than the flexibility in the fifth embodiment.

Various embodiments are illustratively described in the present disclosure. However, various characteristics, aspects, and functions described in one or a plurality of embodiments are not limited to application to a specific embodiment and can be applied to the other embodiments independently or in various combinations. Therefore, innumerable modifications not illustrated are assumed within the scope of the technique disclosed in the specification of this application. For example, the modifications include a case in which at least one constituent element is modified, a case in which at least one constituent element is added or a case in which at least one constituent element is omitted, and, a case in which at least one constituent element is extracted and combined with constituent elements of the other embodiments.

### REFERENCE SIGNS LIST

1 n-type InP substrate; 2 laser diode; 3 EA modulator; 8 modulator electrode; 9 lead-out electrode; 10 electrode pad; 11 gap; 20 wire; 22 cutout

1. A semiconductor optical device comprising:
a semiconductor substrate;
a laser diode provided on the semiconductor substrate;
a modulator provided on the semiconductor substrate, having a modulator electrode, and modulating laser light emitted from the laser diode;
a plurality of lead-out electrodes led out from the modulator electrode; and
a plurality of electrode pads respectively facing the plurality of lead-out electrodes,
wherein a gap is provided between the lead-out electrode and the electrode pad facing each other, and
a tip of the lead-out electrode enters a cutout of the electrode pad.

2. The semiconductor optical device according to claim 1, wherein a width of the gap is 3 μm or more and 10 μm or less.

3. The semiconductor optical device according to claim 1, further comprising a wire bonded to one of the plurality of electrode pads,
wherein the wire is bonded to the lead-out electrode and the electrode pad facing each other across the gap.

4. The semiconductor optical device according to claim 3, wherein the electrode pad to which the wire is bonded is electrically connected to the modulator electrode, and
the electrode pad to which the wire is not bonded is not electrically connected to the modulator electrode.

5. The semiconductor optical device according to claim 1, wherein widths of portions facing each other of the lead-out electrode and the electrode pad are the same.

6. The semiconductor optical device according to claim 1, wherein the electrode pad is a partially cut circle.

7. (canceled)

8. The semiconductor optical device according to claim 1, wherein the tip of the lead-out electrode is linear.

9. The semiconductor optical device according to claim 1, wherein the tip of the lead-out electrode is T-shaped.

10. The semiconductor optical device according to claim 1, wherein the plurality of electrode pads are located only on one side of the modulator electrode.

11. The semiconductor optical device according to claim 1, wherein the plurality of electrode pads are located on both sides of the modulator electrode.
